(19) United States
(12) Patent Application Publication
(10) Pub. No.: US 2020/0243708 A1
(43) Pub. Date: Jul. 30, 2020

(54) LASER LIFT-OFF PROCESSING METHOD AND FLATTENING JIG USED THEREIN

(71) Applicant: V TECHNOLOGY CO., LTD., Yokohama-shi (JP)

(72) Inventors: Yoshikatsu YANAGAWA, Yokohama-shi (JP); Koichiro FUKAYA, Yokohama-shi (JP); Naoya OKURA, Yokohama-shi (JP)

(21) Appl. No.: 16/847,529

(22) Filed: Apr. 13, 2020

Related U.S. Application Data
(63) Continuation of application No. PCT/JP2018/039280, filed on Oct. 23, 2018.

(30) Foreign Application Priority Data
Oct. 31, 2017 (JP) 2017-210858

(51) Int. Cl. H01L 33/00; H01L 21/78; H01L 27/15

(52) U.S. Cl. CPC H01L 33/005; H01L 27/153; H01L 21/7813

(57) ABSTRACT

The present invention provides a laser lift-off processing method performed on a laminate 1 including a sapphire substrate 11 and micro LEDs 12 formed on a first surface of the sapphire substrate, by irradiating the laminate with pulse-oscillated laser light from a second surface of the sapphire substrate and thereby separating the micro LEDs therefrom. The method includes: flattening the sapphire substrate by pressing it with an external force to correct its warpage; and separating the micro LEDs from the flattened sapphire substrate by irradiating the laminate with the laser light from the second surface while moving the laminate placed on a stage 91 relative to an optical system 6 such that the laser focal point sequentially coincides with boundary portions between the sapphire substrate and the micro LEDs. The method allows for satisfactorily separating the micro LEDs from the sapphire substrate even if it is warped.

This application is a continuation application of PCT/JP2018/039280, filed on Oct. 23, 2018.

### BACKGROUND OF THE INVENTION

### Field of the Invention

The present invention relates to a method of laser lift-off processing in a manufacturing process of a flat-panel display including micro light emitting diodes (LEDs) as pixel elements, and specifically relates to a method of performing laser lift-off processing on a laminate including a sapphire substrate and micro LEDs formed thereon so as to separate the micro LEDs from the sapphire substrate. In particular, the present invention relates to a laser lift-off processing method and a flattening jig used therein that are reliably applicable to even such a laminate including a warped sapphire substrate, by correcting the warpage and improving the flatness of the sapphire substrate to facilitate separating the micro LEDs from the sapphire substrate.

### Description of Related Art

Methods for manufacturing semiconductor devices using laser lift-off have been conventionally known in the art. In such a method, a semiconductor laminate including a light-emitting semiconductor layer is stacked onto a sapphire substrate, and the sapphire substrate is then removed by laser lift-off, that is, by using laser irradiation to separate the sapphire substrate from the semiconductor laminate at the boundaries therebetween. However, when the sapphire substrate has some warpage, the focal point of the laser light may not be constantly placed at the boundaries during laser irradiation, and thus, the sapphire substrate may not be reliably removed by laser lift-off (see JP 2011-044477 A, for example).

As a technique to address the above situation, JP 2011-044477 A discloses a semiconductor structure that prevents the warpage of the sapphire substrate, for example. Specifically, J P 2011-044477 A discloses an optical semiconductor device including: a semiconductor laminate including a light-emitting semiconductor layer; a first metal body including one or more metal layers formed on the semiconductor laminate; a support substrate; and a second metal body including one or more metal layers formed on the support substrate.

However, adopting such a complex semiconductor structure as described above requires extra work in the manufacturing process. Furthermore, in consideration of the structure of a micro LED, it is likely to be difficult to adopt a semiconductor structure as disclosed in JP 2011-044477 A as a measure to prevent the warpage of the sapphire substrate in a manufacturing process of a flat-panel display including, as pixel elements, micro LEDs each having a very small size of less than 1 mm (LEDs of micron order), for example.

### SUMMARY OF THE INVENTION

The present invention has been made to address the above problems, and has an object to provide a laser lift-off processing method and a flattening jig used in laser lift-off processing according to the method that allows for satisfactorily separating micro LEDs from even a warped sapphire substrate, with no need to adopt a semiconductor structure that prevents the warpage of the sapphire substrate.

To achieve the above object, a laser lift-off processing method according to an aspect of the present invention is provided. The laser lift-off processing method is performed on a laminate including a disk-shaped sapphire substrate, which is to be removed, and a plurality of micro LEDs formed on a first surface of the sapphire substrate, by irradiating the laminate with pulse-oscillated laser light from a second surface of the sapphire substrate and thereby separating the micro LEDs from the sapphire substrate. The laser lift-off processing method includes flattening the sapphire substrate by pressing the sapphire substrate with a force external to the laminate so as to correct a warpage of the sapphire substrate; and separating the micro LEDs from the sapphire substrate by irradiating the laminate with the laser light from the second surface in a state in which the sapphire substrate is flattened while moving, in a horizontal plane, the laminate placed on a stage of a conveying mechanism relative to an irradiation optical system from which the laser light exits, such that a focal point of the laser light sequentially coincides with boundary portions between the sapphire substrate and the micro LEDs.

To achieve the above object, a flattening jig according to an aspect of the present invention is provided. The flattening jig is used in a laser lift-off processing method performed on a laminate including a disk-shaped sapphire substrate, which is to be removed, and a plurality of micro LEDs formed on a first surface of the sapphire substrate, by irradiating the laminate with pulse-oscillated laser light from a second surface of the sapphire substrate and thereby separating the micro LEDs from the sapphire substrate. The flattening jig is configured to flatten the sapphire substrate by pressing the sapphire substrate so as to correct a warpage of the sapphire substrate. The flattening jig includes: a ring member having a diameter greater than a diameter of the sapphire substrate; an inner annular portion having a flat surface protruding radially inward from an upper end periphery of the ring member; and an outer annular portion having a flat surface protruding radially outward from a lower end periphery of the ring member.

In the laser lift-off processing method according to an aspect of the present invention, the sapphire substrate is flattened by pressing the sapphire substrate with an external force so as to correct the warpage of the sapphire substrate. Thus, the focal point of the laser light is constantly placed at appropriate positions and the laser lift-off processing can be performed satisfactorily with no need to adopt a semiconductor structure that prevents the warpage of the sapphire substrate.

Furthermore, using the flattening jig according to an aspect of the present invention in the step of flattening the sapphire substrate of the laser lift-off processing method according an aspect of the present invention makes it possible to press the sapphire substrate so as to correct its warpage and flatten it.

### BRIEF DESCRIPTION OF THE DRAWINGS

FIG. 1 is a configuration diagram of a laser lift-off apparatus used in a laser lift-off processing method according to a first embodiment.

FIG. 2 is a block diagram illustrating an exemplary hardware configuration of a computer shown in FIG. 1.

FIG. 3 is a plan view of an example of a laminate according to the first embodiment.

FIG. 4 is a cross-sectional view taken along line A-A of FIG. 3.

FIG. 5 is a flowchart of the laser lift-off processing according to the first embodiment.

FIGS. 6A and 6B are diagrams for illustrating positioning of the laminate according to the first embodiment.

FIGS. 7A to 7C are time-sequence diagrams showing the progress of flattening processing according to the first embodiment.

FIGS. 8A and 8B illustrate a state after the flattening processing according to the first embodiment is completed.

FIGS. 9A and 9B are diagrams for illustrating positioning of the laminate according to a second embodiment.

FIGS. 10A to 10C are time-sequence diagrams showing the progress of flattening processing according to the second embodiment.

FIGS. 11A and 11B illustrate a state after the flattening processing according to the second embodiment is completed.

FIGS. 12A to 12C are time-sequence diagrams showing the progress of flattening processing according to a third embodiment.

FIGS. 13A to 13C are time-sequence diagrams showing the progress of flattening processing according to a fourth embodiment.

FIGS. 14A to 14D are time-sequence diagrams showing the progress of flattening and laser lift-off processing according to a fifth embodiment.

FIGS. 15A to 15C are diagrams illustrating a modification of the fifth embodiment.

FIG. 16 is a diagram illustrating a comparative example.

### DESCRIPTION OF PREFERRED EMBODIMENTS

Hereinafter, embodiments of the present invention will be described in detail with reference to the accompanying drawings. To facilitate understanding of the present invention, an exemplary configuration of a laser lift-off apparatus used in a laser lift-off processing method according to the present invention will be described first.

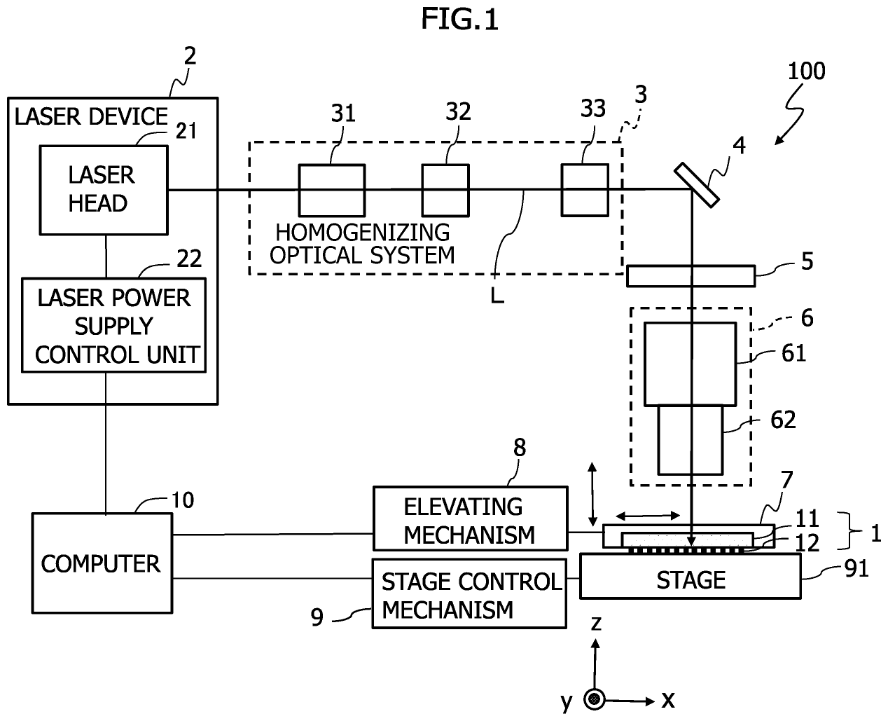

FIG. 1 is a configuration diagram of a laser lift-off apparatus used in a laser lift-off processing method according to a first embodiment. A laser lift-off apparatus 100 is configured to perform laser lift-off processing on a laminate 1 including a sapphire substrate 11, which is to be removed, and a plurality of micro LEDs 12 formed on one surface (first surface) of the sapphire substrate 11. Specifically, the laser lift-off apparatus 100 is configured to irradiate the laminate 1 with pulse-oscillated laser light from the other surface (second surface) of the sapphire substrate 11 and thereby separate the micro LEDs 12 from the sapphire substrate 11. The laser lift-off apparatus 100 includes a laser device 2, a homogenizing optical system 3, a mirror 4, a projection mask 5, a reducing optical system 6, a flattening jig 7, an elevating mechanism 8, a stage control mechanism 9, and a computer 10.

The laser device 2 is configured to emit pulse laser light L by laser oscillation, and includes a laser head 21 and a laser power supply control unit 22. The laser device 2 may, for example, be configured to emit laser light L having a small pulse width on the order of picoseconds by using an yttrium aluminum garnet (YAG) laser with a deep ultraviolet output at 266 nm of wavelength (fourth-harmonic wavelength). Here, the processing energy density of the laser light L may be set to 200 mJ/cm² or more and less than a level that will not cause adverse effects such as contamination by laser ablation, for example. It has also been confirmed through experiments that, to perform the laser lift-off processing according to the first embodiment satisfactorily, it is preferable that the wavelength of the laser light does not exceed 300 nm. Accordingly, in the first embodiment, a KrF excimer laser operating at a wavelength of 248 nm may alternatively be used, for example.

The laser head 21 may be a lamp-pumped YAG laser device, for example. The laser power supply control unit 22 is configured to control a laser power supply (not shown). Specifically, the laser power supply control unit 22 specifies a laser output value based on a control signal received from the computer 10, and supplies power to the laser head 21 in accordance with the laser output value. The laser device 2 is configured to emit laser light L (laser pulse) from the laser head 21 in response to the receipt of a trigger signal from a pulse generator (not shown). The laser light L acts as a laser beam.

The homogenizing optical system 3 is configured primarily to homogenize the intensity distribution of the laser beam, and includes optical elements such as a beam expanding lens 31, a homogenizer lens 32, and a condenser lens 33. The beam expanding lens 31 is configured to expand a laser beam. The homogenizer lens 32, which is an optical element that controls the profile of a laser beam, is configured to convert a laser beam with a Gaussian distribution profile, in which intensity varies radially, peaking at the beam axis, into a laser beam with a uniform intensity distribution profile. The condenser lens 33 is configured, for example, to shape the laser light L that has passed through the homogenizer lens 32 into a laser beam having a rectangular cross section that ensures that a predetermined region of the sapphire substrate 11 can be accurately irradiated with the laser beam.

The laser light L that has passed through the condenser lens 33 travels along the optical path deflected by the mirror 4 and enters the projection mask 5. The projection mask 5 is a slit that makes the laser beam have a predetermined shape. The laser light L that has passed through the light transmitting region of the projection mask 5 is then guided to an irradiation-target region of the sapphire substrate 11 via the reducing optical system 6 so that a reduced image of the light transmitting region is projected onto the irradiation-target region.

The reducing optical system 6 is configured to guide the laser light L that has passed through the projection mask 5 so that a reduced image of the light transmitting region is projected onto the processing-target surface of the laminate 1, and includes a microscope 61 and an objective lens 62. The reducing optical system 6 is an example of an irradiation optical system from which the laser light L exits. For instance, when the sapphire substrate 11 before being subjected to flattening has a flatness (ΔZ) of 100 μm (micrometers), it is desirable that the sapphire substrate 11 after being subjected to flattening have a flatness (ΔZ) of 20 μm or less (i.e., ±10 μm or less), in the first embodiment. In this case, in order to constantly place the focal point of the laser light L on appropriate positions under the condition in which the sapphire substrate 11 has a flatness (ΔZ) of 20 μm or less (i.e., ±10 μm or less), the reducing optical system 6 is configured to achieve 0.02× reduction projection. That is, in the first embodiment, the reduction rate in reduction projection may be changed as appropriate according to the flatness of the sapphire substrate 11 before being subjected to flattening.

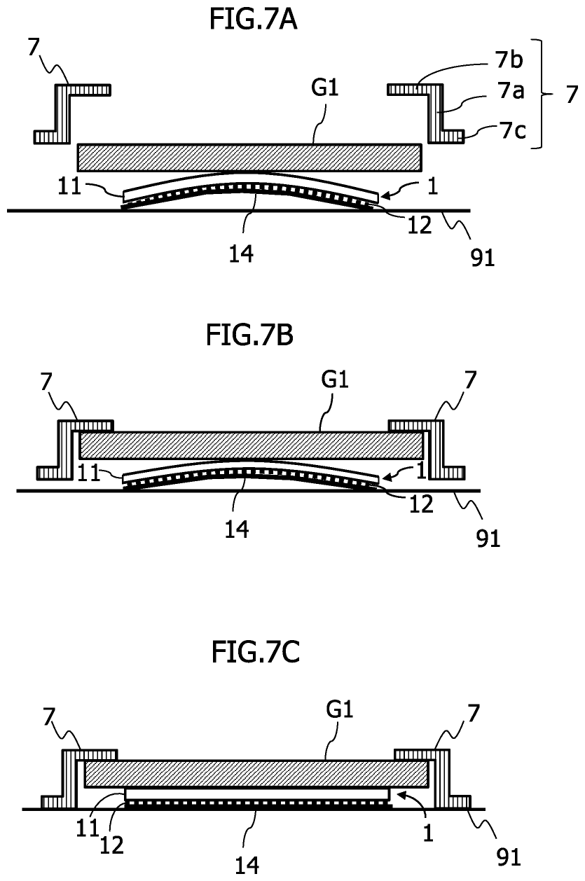

The flattening jig 7 is configured to flatten the sapphire substrate 11 by pressing the sapphire substrate 11 with an external force so as to correct the warpage of the sapphire substrate 11. The external force may be an external pressure, for example. The intensity of this pressure is high enough to flatten the sapphire substrate 11 and low enough not to affect the micro LEDs 12. This will be described later in more detail with reference to FIGS. 7 to 13. The elevating mechanism 8 is configured to elevate and lower the flattening jig 7 and at least one quartz glass substrate in the z-axis direction (see FIG. 1). The quartz glass substrate is an example of a transmissive member. This transmissive member is adapted to transmit deep ultraviolet laser light. The elevating mechanism 8, which includes an elevation control unit (not shown), is configured to cause the elevation control unit to elevate and lower the flattening jig 7 and the quartz glass substrate in the z-axis direction, based on a control signal from a control unit 10a.

The stage control mechanism 9 is configured to move the laminate 1 in a horizontal plane, specifically configured to control a stage 91 for conveying and positioning the laminate 1. The stage control mechanism 9 is an example of a conveying mechanism. The stage 91 may be an XYθ stage that allows for position and posture adjustment control in the in-plane directions of the stage, for example. The stage control mechanism 9 includes a stage control unit (not shown), and is configured to cause the stage control unit to convey and position the laminate 1 placed on the stage 91, based on a control signal from the computer 10. The stage control mechanism 9 may be implemented using a known conveying means and a known positioning means.

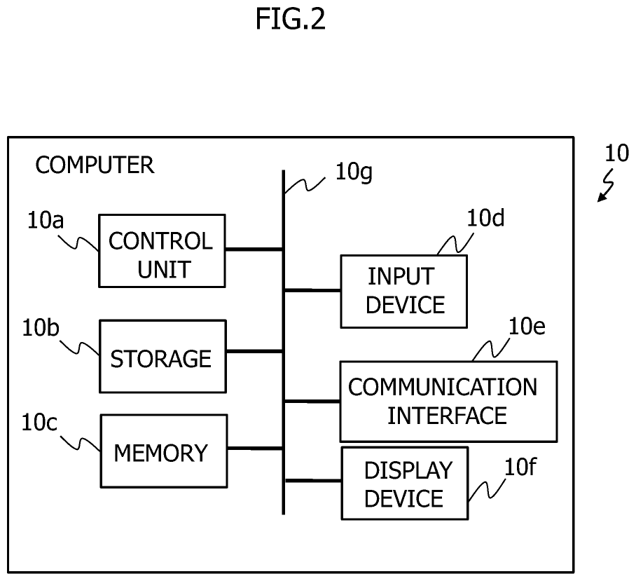

FIG. 2 is a block diagram illustrating an exemplary hardware configuration of the computer shown in FIG. 1. The computer 10 is configured to control the laser lift-off apparatus 100, and includes the control unit 10a, a storage 10b, a memory 10c, an input device 10d, a communication interface 10e, a display device 10f, and a bus 10g. The control unit 10a, the storage 10b, the memory 10c, the input device 10d, the communication interface 10e, and the display device 10f are connected to each other through the bus 10g. The computer 10 is connected the laser device 2, the elevating mechanism 8, and the stage control mechanism 9 through a communication line in order, for example, to transmit control signals to the laser device 2, the elevating mechanism 8 and, the stage control mechanism 9.

The control unit 10a has a processor function, for example, and is configured to perform the control implemented in the computer 10. The storage 10b is a storage device such as a hard disk drive (HDD) or a flash memory, and stores therein programs and various data.

The memory 10c is a storage device such as a random access memory (RAM), and is loaded with programs executed by the control unit 10a, for example. The input device 10d may be a keyboard based or touch screen based input device, for example. The communication interface 10e includes a communication interface for data communication, for example. The display device 10f may, for example, be a liquid crystal monitor, and is configured to display an operation menu screen and/or an output result in response to an instruction from the control unit 10a.

In addition, the computer 10 is configured to perform various functions by executing programs through cooperation of the hardware devices such as the control unit 10a, the storage 10b, and the memory 10c. These programs include a control program for performing the laser lift-off processing method.

The control program causes the computer 10 to perform processing including the steps of: flattening the sapphire substrate 11 by pressing the sapphire substrate 11 with a force external to the laminate 1 so as to correct the warpage of the sapphire substrate 11; and separating the micro LEDs 12 from the sapphire substrate 11 by irradiating the laminate 1 with laser light L from the surface, opposite to the surface on which the micro LEDs 12 are formed, of the sapphire substrate 11 in a state in which the sapphire substrate 11 is flattened while moving, in a horizontal plane, the laminate 1 placed on the stage 91 of the stage control mechanism 9 relative to the reducing optical system 6 from which the laser light L exits, such that the focal point of the laser light L sequentially coincides with boundary portions between the sapphire substrate 11 and the micro LEDs 12. In accordance with this control program, the control unit 10a controls the laser device 2, the elevating mechanism 8, and the stage control mechanism 9 in an integrated manner.

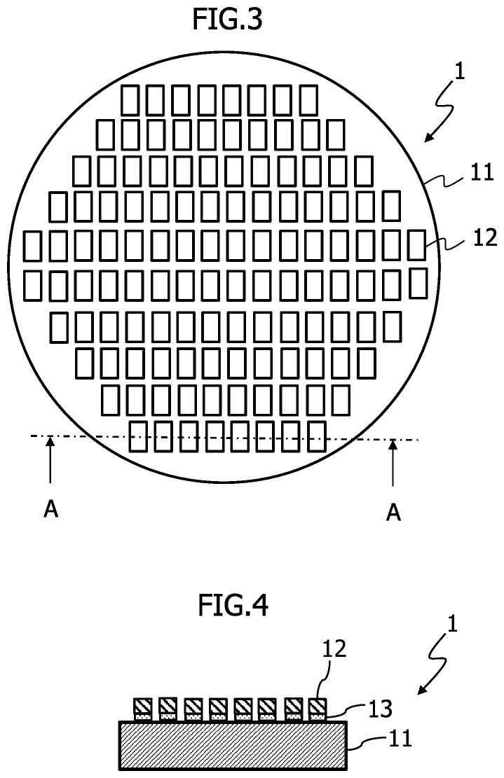

FIG. 3 is a plan view of an example of a laminate according to the first embodiment. The laminate 1 includes the sapphire substrate 11 and the micro LEDs 12 formed on the one surface of the sapphire substrate 11. The sapphire substrate 11 is formed in a disk shape and may, for example, have any diameter within the range of 2 to 8 inches. Note that the “disk shape” herein refer to a substantially disk-shaped member and may also refer to one having one or more notches. The actual thickness of the sapphire substrate 11 may be 0.2 mm, for example. The actual dimensions of each micro LED 12 may be 15 μm (width)×30 μm (length)×6 μm (thickness), for example.

FIG. 4 is a cross-sectional view taken along line A-A of FIG. 3. Although the laminate 1 is illustrated as having no warpage in the sapphire substrate 11 in FIG. 4, this is merely for convenience of explanation. The laminate 1 has a boundary portion 13 between the sapphire substrate 11 and each of the micro LEDs 12. The boundary portion 13 is a release layer for laser lift-off processing. When the laminate 1 is irradiated with laser light such that its focal point coincides with the release layer, the release layer is processed by laser ablation to produce nitrogen gas, for example. The laser lift-off processing uses the pressure of the nitrogen gas thus produced to separate each micro LED 12 from the sapphire substrate 11. The “release layer” herein may also be referred to as “sacrificial layer”. Laser lift-off techniques are well known and need not be described in further detail herein. Although the boundary portion 13 is not shown in the drawings related to the following description, this is merely for convenience of explanation. The sapphire substrate 11 has one surface (first surface) and the other surface (second surface), which is opposite to the one surface. In the following description regarding the sapphire substrate 11, the one surface (first surface) on which the micro LEDs 12 are formed will be referred to as “upper surface” and the other surface (second surface) from which the laminate 1 is irradiated with the laser light L will be referred to as “lower surface”, based on the positional relationship shown in FIG. 4.

Next, the operation of the laser lift-off apparatus 100 configured as described above and the laser lift-off processing using the laser lift-off apparatus 100 will be described. The laser lift-off processing is integrated in the process for manufacturing a micro-LED flat panel display.

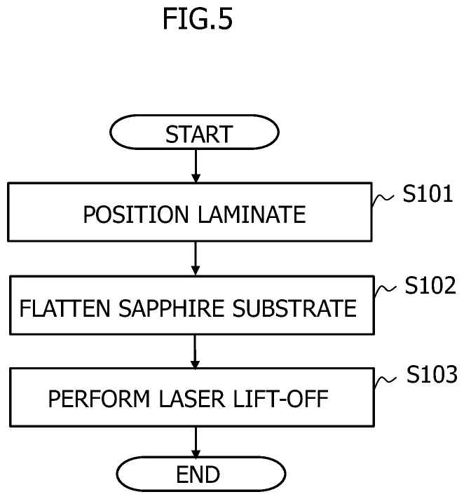

FIG. 5 is a flowchart of the laser lift-off processing according to the first embodiment. First, the laser lift-off apparatus 100 shown in FIG. 1 is turned on and shifts to a state ready for laser irradiation. When the control unit 10a receives an input of instruction to start the laser lift-off processing from an operator via the input device 10d, the control unit 10a starts the processing illustrated in the flowchart of FIG. 5 based on the control program for performing the laser lift-off processing.

In step S101, the control unit 10a positions the laminate 1. Specifically, first, the control unit 10a transmits, to the stage control mechanism 9, the control signal for positioning the laminate 1 at an appropriate location for irradiation of the laser light L. Upon receiving the control signal, the stage control mechanism 9 positions the laminate 1 at the appropriate location for irradiation.

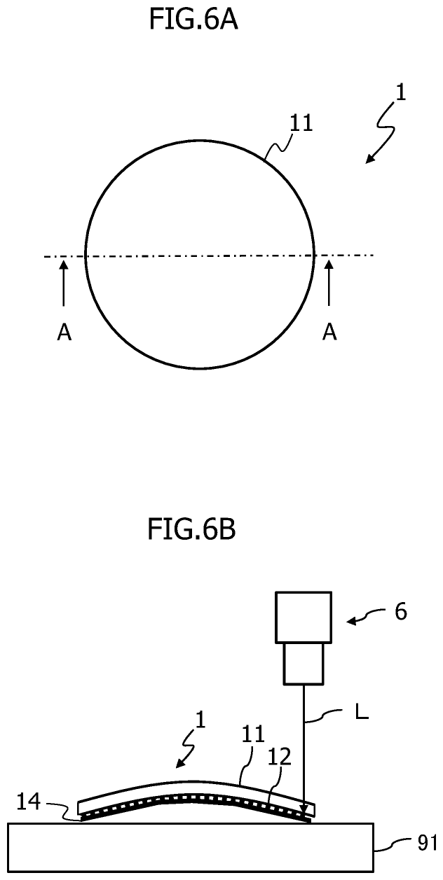

FIGS. 6A and 6B are diagrams for illustrating the positioning of the laminate 1. FIG. 6A is a plan view of the laminate 1 after the positioning is completed. FIG. 6B, which includes a cross-sectional view taken along line A-A of FIG. 6A, illustrates the positional relationship between the reducing optical system 6 and the processing start position from which laser irradiation starts. The ends, distal from the sapphire substrate 11, of the micro LEDs 12, which are formed on the upper surface of the sapphire substrate 11, are adhered to an adhesive film 14. In other words, the micro LEDs 12 are placed on the stage 91 with the film 14 interposed therebetween. This aims at preventing scattering of the micro LEDs 12 after they are separated from the sapphire substrate 11 by laser lift-off, and allowing for reversing the film 14 together with the micro LEDs 12 as necessary to facilitate transferring of the micro LEDs 12 in a step subsequent to this laser lift-off processing in the manufacturing process. When the positioning is completed, the stage control mechanism 9 transmits, to the control unit 10a, a signal indicating completion of positioning, and then the operation proceeds to step S102.

In step S102, the control unit 10a performs processing for flattening the sapphire substrate 11.

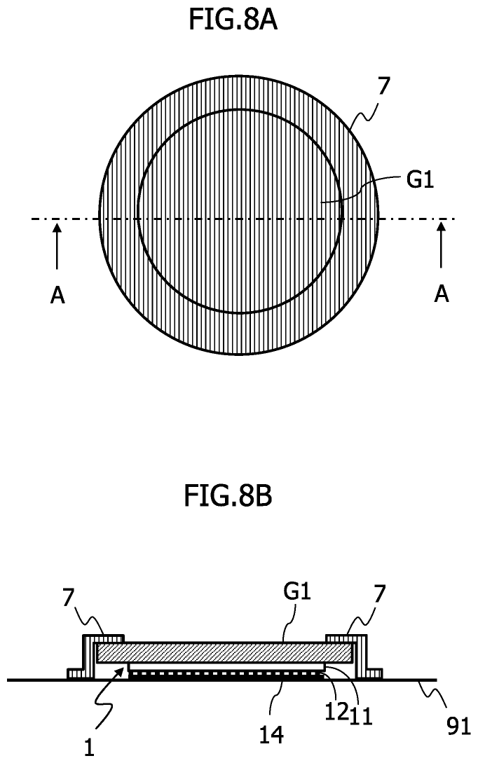

FIGS. 7A to 7C are time-sequence diagrams showing the progress of the flattening processing according to the first embodiment. FIGS. 8A and 8B illustrate a state after the flattening processing is completed. FIGS. 7A to 7C are three illustrative sequential stages of the progress of the flattening processing. FIG. 8A is a plan view of an arrangement including the flattening jig 7, a quartz glass substrate G1, and the sapphire substrate 11 as viewed vertically downward from the reducing optical system 6 of FIG. 1. FIG. 8B is a cross-sectional view taken along line A-A of FIG. 8A. Note that the drawings related to the following description show not an entire structure of the stage 91, but only the horizontal plane defined thereby, for convenience of explanation.

The control unit 10a transmits a control signal that instructs the elevating mechanism 8 to perform the flattening processing. Upon receiving the control signal, the elevating mechanism 8 lowers the quartz glass substrate G1 that transmits the laser light L to the laminate 1 so that the quartz glass substrate G1 comes into contact with the lower surface of the sapphire substrate 11 (see FIG. 7A). Then, the elevating mechanism 8 lowers the flattening jig 7 configured to press a peripheral portion of the quartz glass substrate G1 (see FIG. 7B).

Here, the flattening jig 7 is used in the laser lift-off processing method according to the present invention, and it is configured to flatten the sapphire substrate 11 by pressing the sapphire substrate 11 so as to correct its warpage. Specifically, the flattening jig 7 includes a ring member 7a, an inner annular portion 7b, and an outer annular portion 7c. The ring member 7a has a diameter greater than the diameter of the sapphire substrate 11. The inner annular portion 7b has a flat surface protruding radially inward from the upper end periphery of the ring member 7a. The outer annular portion 7c has a flat surface protruding radially outward from the lower end periphery of the ring member 7a.

When the elevating mechanism 8 lowers the flattening jig 7, the flattening jig 7 presses the peripheral portion of the quartz glass substrate G1, thereby pressing the sapphire substrate 11 so as to correct its warpage and flatten it (see FIG. 7C). Thus, the sapphire substrate 11 can be easily flattened by using the flattening jig 7. The flattening jig 7 may be made of a magnetic metal and fixed on the stage 91 by magnetic adsorption, for example. This prevents the laminate 1 from moving out of place. However, in the first embodiment, the method for fixing the flattening jig 7 is not limited to using magnetic adsorption and may be using air suction. When the flattening processing is completed, the elevating mechanism 8 transmits, to the control unit 10a, a signal indicating completion of flattening, and then the operation proceeds to step S103.

In step S103, the control unit 10a performs laser lift-off processing. Specifically, the control unit 10a transmits, to the laser device 2 and the stage control mechanism 9, control signals that instruct them to perform laser lift-off processing. In response, the laser device 2 irradiates the laminate 1 with laser light L from the lower surface of the sapphire substrate 11 while the stage control mechanism 9 moves the laminate 1 placed on the stage 91 relative to the reducing optical system 6 from which the laser light L exits, such that the focal point of the laser light L sequentially coincides with boundary portions between the sapphire substrate 11 and the micro LEDs 12. In this way, the micro LEDs 12 shown in FIG. 3 are separated from the sapphire substrate 11. Here, the laminate 1 placed on the stage 91 may be moved relative to the reducing optical system 6 from which the laser light L exits by, for example, a method in which the control unit 10a causes the stage control mechanism 9 to move the laminate 1 placed on the stage 91 along a predetermined path in a horizontal plane while the reducing optical system 6 is maintained unmoved. When the control unit 10a determines that all the micro LEDs 12 are separated from the sapphire substrate 11, the processing in the flowchart of FIG. 5 ends.

As described above, in the laser lift-off processing method according to the first embodiment, the sapphire substrate 11 is pressed with a force external to the laminate 1 so as to correct the warpage of the sapphire substrate 11 and flatten it. Thus, even when the sapphire substrate 11 has some warpage, the sapphire substrate 11 is flattened so that the focal point of the laser light L is constantly placed at appropriate positions and the laser lift-off processing can be performed satisfactorily. Furthermore, according to the first embodiment, the flattening jig 7 for use in the laser lift-off processing is provided. Note that, although the micro LEDs 12 are irradiated with laser light one by one in the first embodiment, two or more of the micro LEDs 12 may be irradiated with line beams or the like at each irradiation.

Next, second to fifth embodiments will be described. As in the first embodiment, the laser lift-off apparatus 100 shown in FIG. 1 is used in the second to fifth embodiments. In the following description for each embodiment, differences from the other embodiments will be discussed in detail, among other features. A particular feature of the second embodiment is the use of a support 74 for pressing down the film 14. The support 74 may be made of a magnetic metal, for example. Note that the same components as those in the first embodiment are indicated by the same reference numerals and description thereof will be omitted.

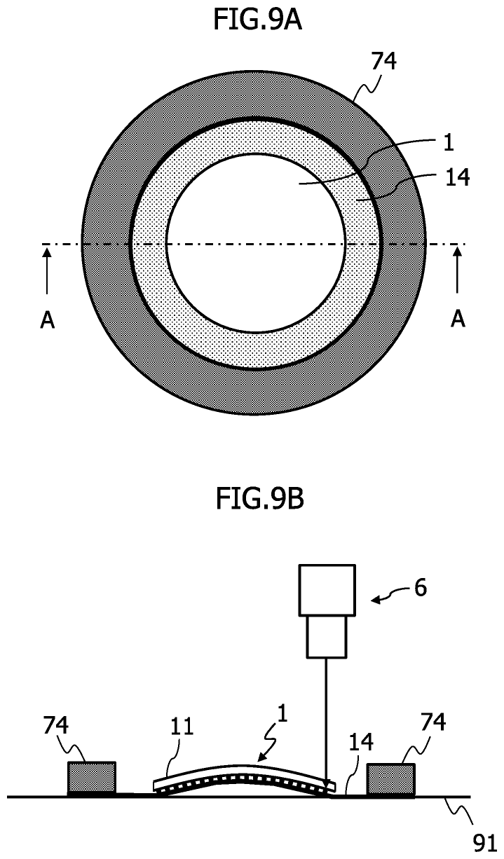

FIGS. 9A and 9B are diagrams for illustrating the positioning of the laminate 1 according to the second embodiment. FIG. 9A is a plan view of the laminate 1 after the positioning is completed. FIG. 9B, which includes a cross-sectional view taken along line A-A of FIG. 9A, illustrates the positional relationship between the reducing optical system 6 and the processing start position from which laser irradiation starts. The support 74 is a ring-shaped member and configured to press the film 14 in a region surrounding the laminate 1 that is placed on the film 14.

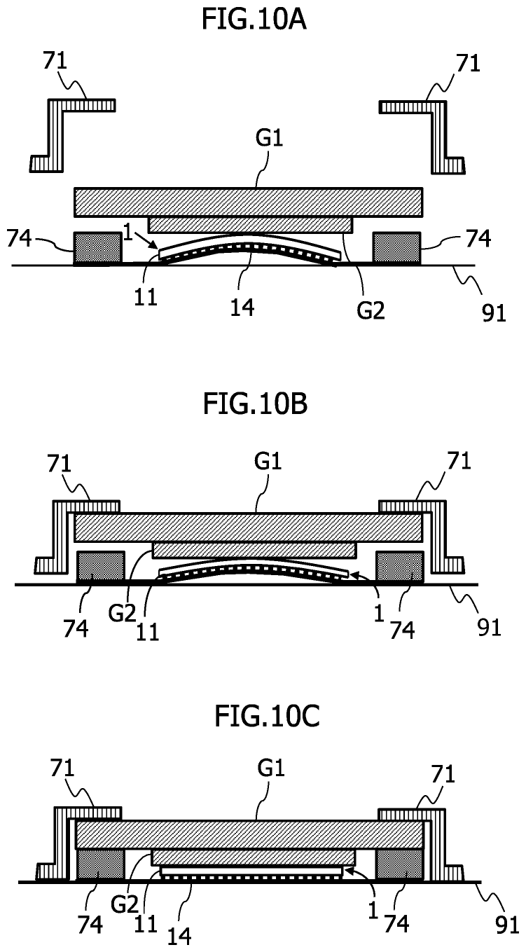

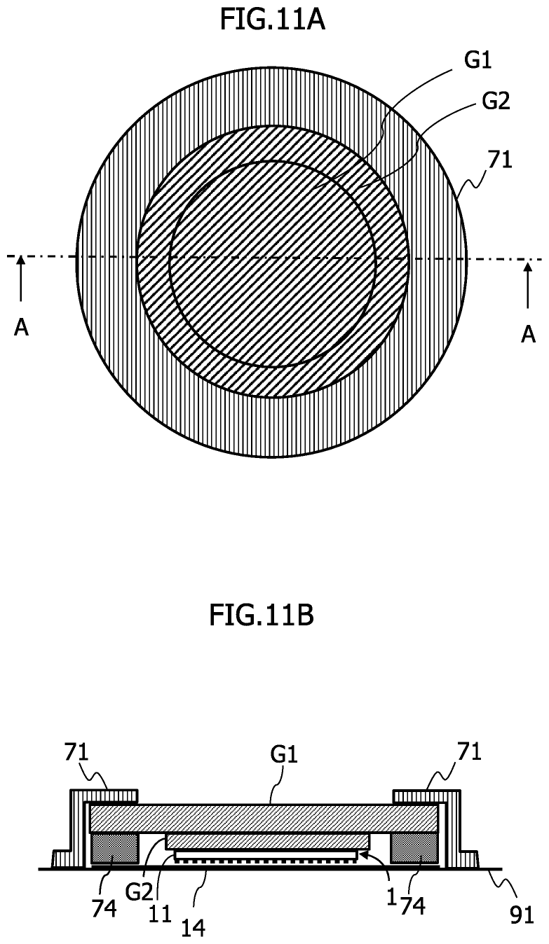

FIGS. 10A to 10C are time-sequence diagrams showing the progress of the flattening processing according to the second embodiment. FIGS. 11A and 11B illustrate a state after the flattening processing according to the second embodiment is completed. As with FIGS. 7A to 7C, FIGS. 10A to 10C are three illustrative sequential stages of the progress of the flattening processing.

A flattening jig 71 shown in FIGS. 11A and 11B has the same configuration as the flattening jig 7 shown in FIGS. 7A to 7C. FIG. 11A is a plan view of an arrangement including the flattening jig 71, the quartz glass substrate G1, and a quartz glass substrate G2 as viewed vertically downward from the reducing optical system 6 of FIG. 1. FIG. 11B is a cross-sectional view taken along line A-A of FIG. 11A. In the second embodiment, two quartz glass substrates G1, G2 having different diameters are used. Specifically, the transmissive member used in the second embodiment is made of combination of the quartz glass substrate G1 having a disk shape with a diameter greater than the diameter of the sapphire substrate 11 and the quartz glass substrate G2 having a disk shape with a diameter substantially the same as the diameter of the sapphire substrate 11.

In the second embodiment, the transmissive member is lowered so that the quartz glass substrate G2 comes into contact with the lower surface of the sapphire substrate 11 (see FIG. 10A). Then, the flattening jig 71, which is configured to press the peripheral portion of the quartz glass substrate G1, is lowered so that the flattening jig 71 presses the quartz glass substrates G1, G2 and causes them to press the sapphire substrate 11 so as to correct its warpage (see FIG. 10B). In this way, the sapphire substrate 11 is flattened (see FIG. 10C). Thus, in the second embodiment as well, the focal point of the laser light L is constantly placed at appropriate positions and the laser lift-off processing can be performed satisfactorily. Although obvious enough, the transmissive member according to the second embodiment is not limited to non-integrated combination of the two quartz glass substrates G1, G2, and may alternatively be formed integrally in one piece to have the same structure. The second embodiment, which uses the support 74, allows preventing the edges of the film 14 from being curled up after the laser lift-off processing is completed, in addition to providing the same effects as in the first embodiment.

Next, the third embodiment will be described. A particular feature of the third embodiment is further providing a cushion member on the flattening jig, and the third embodiment is the same as the second embodiment in the other respects.

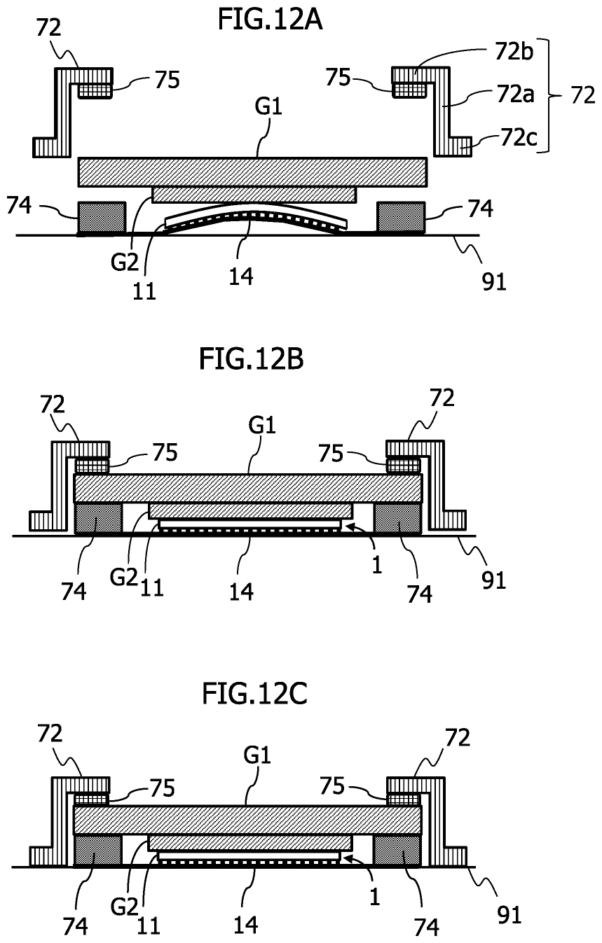

FIGS. 12A to 12C are time-sequence diagrams showing the progress of the flattening processing according to the third embodiment. Note that illustration of a state after the flattening processing according to the third embodiment is completed is not included in the attached drawings. This is because, other than the presence or absence of the cushion member, there is no difference between the third embodiment and the second embodiment, and the plan view as viewed vertically downward from the reducing optical system 6 of FIG. 1 according to the third embodiment is substantially the same as FIG. 11A. As shown in FIGS. 12A to 12C, a flattening jig 72 includes a ring member 72a, an inner annular portion 72b, and an outer annular portion 72c. The ring member 72a has a diameter greater than the diameter of the sapphire substrate 11. Furthermore, a ring-shaped cushion member 75 is provided on the lower surface of the inner annular portion 72b. The cushion member 75 may be a spring or any elastic body made of elastic rubber or resin.

In the third embodiment, the control unit 10a transmits a control signal that instructs the elevating mechanism 8 shown in FIG. 1 to perform the flattening processing. Upon receiving the control signal, the elevating mechanism 8 lowers the quartz glass substrate G2 so that it comes into contact with the lower surface of the sapphire substrate 11. Then, the elevating mechanism 8 lowers the quartz glass substrate G1 so that it comes into contact with the quartz glass substrate G2 (see FIG. 12A). After that, the elevating mechanism 8 lowers the flattening jig 72 so that the flattening jig 72 presses the cushion member 75 against the peripheral portion of the quartz glass substrate G1 (see FIG. 12B). In this way, the elevating mechanism 8 finally flattens the sapphire substrate 11 (see FIG. 12C). As described above, in the third embodiment, the pressing force is buffered by the cushion member 75, which absorbs excess force that otherwise can act on the laminate 1. Furthermore, in the third embodiment as well, the sapphire substrate 11 is flattened so that the focal point of the laser light L is constantly placed at appropriate positions and the laser lift-off processing can be performed satisfactorily.

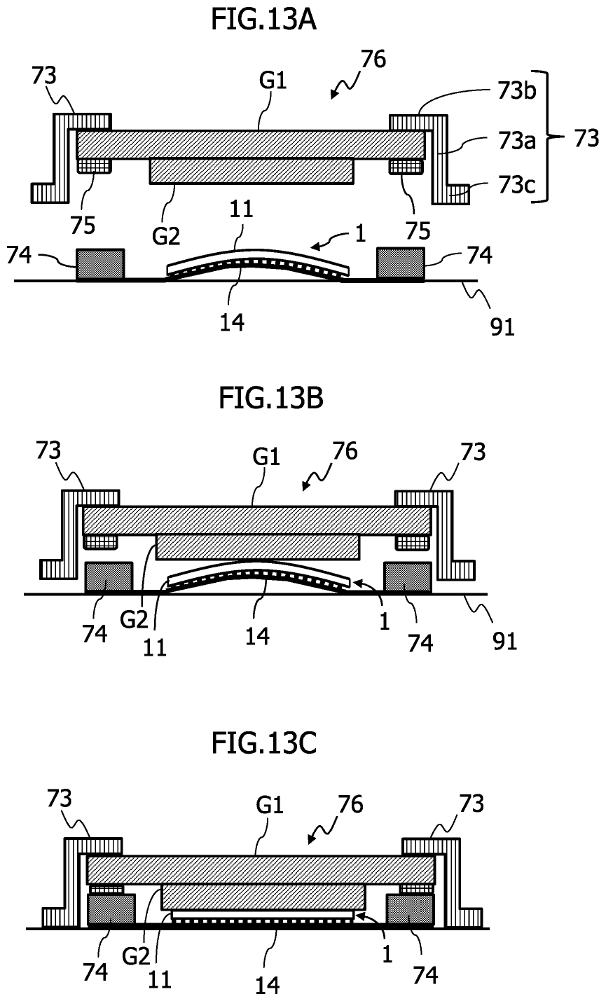

Next, the fourth embodiment will be described. FIGS. 13A to 13C are time-sequence diagrams showing the progress of the flattening processing according to the fourth embodiment. A particular feature of the fourth embodiment is the use of a press member 76 formed by integrally combining the quartz glass substrates G1, G2 that transmit the laser light L and a flattening jig 73 configured to press the peripheral portion of the quartz glass substrate G1. Specifically, in the step of flattening the sapphire substrate 11 according to the fourth embodiment, the press member 76 is lowered to the laminate 1 so that the quartz glass substrate G2 comes into contact with the lower surface of the sapphire substrate 11, thereby pressing the sapphire substrate 11 so as to correct its warpage. The flattening jig 73 includes a ring member 73a, an inner annular portion 73b, and an outer annular portion 73c. The ring member 73a has a diameter greater than the diameter of the sapphire substrate 11. The upper surface of the peripheral portion of the quartz glass substrate G1 is fixed to the lower surface of the inner annular portion 73b. This configuration allows the sapphire substrate 11 to be pressed and its warpage is corrected with only a single lowering operation of the elevating mechanism 8. A further particular feature of the fourth embodiment is that the ring-shaped cushion member 75 is provided on the lower surface of the peripheral portion of the quartz glass substrate G1.

In the fourth embodiment, the control unit 10a transmits the control signal that instructs the elevating mechanism 8 shown in FIG. 1 to perform the flattening processing. Upon receiving the control signal, the elevating mechanism 8 lowers the press member 76 (see FIG. 13A) so that the quartz glass substrate G2 comes into contact with the lower surface of the sapphire substrate 11 (see FIG. 13B). Then, the elevating mechanism 8 further lowers the press member 76 so that the peripheral portion of the quartz glass substrate G1 is pressed against the cushion member 75. Thereby, the quartz glass substrate G2 presses the sapphire substrate 11 so as to correct its warpage. In this way, the press member 76 finally flattens the sapphire substrate 11 (see FIG. 13C). As described above, in the fourth embodiment, the pressing force is buffered by the cushion member 75, which absorbs excess force that otherwise can act on the laminate 1. Furthermore, in the fourth embodiment as well, the focal point of the laser light L is constantly placed at appropriate positions and the laser lift-off processing can be performed satisfactorily.

Next, the fifth embodiment will be described. A particular feature of the fifth embodiment is that, after the sapphire substrate 11 is flattened by pressing the sapphire substrate 11 with an external force so as to correct the warpage of the sapphire substrate 11 and the laminate 1 are then bonded and integrated onto a transmissive member made of quartz glass and/or the like, the laser lift-off processing is performed on the laminate 1. Specifically, in the step of flattening the sapphire substrate 11 according to the fifth embodiment, after the transmissive member that transmits the laser light L is lowered so that it comes into contact with the lower surface of the sapphire substrate 11 and is then pressed onto the sapphire substrate 11 so as to correct its warpage and flatten it, a peripheral portion of the sapphire substrate 11 is fixed to the transmissive member with an adhesive.

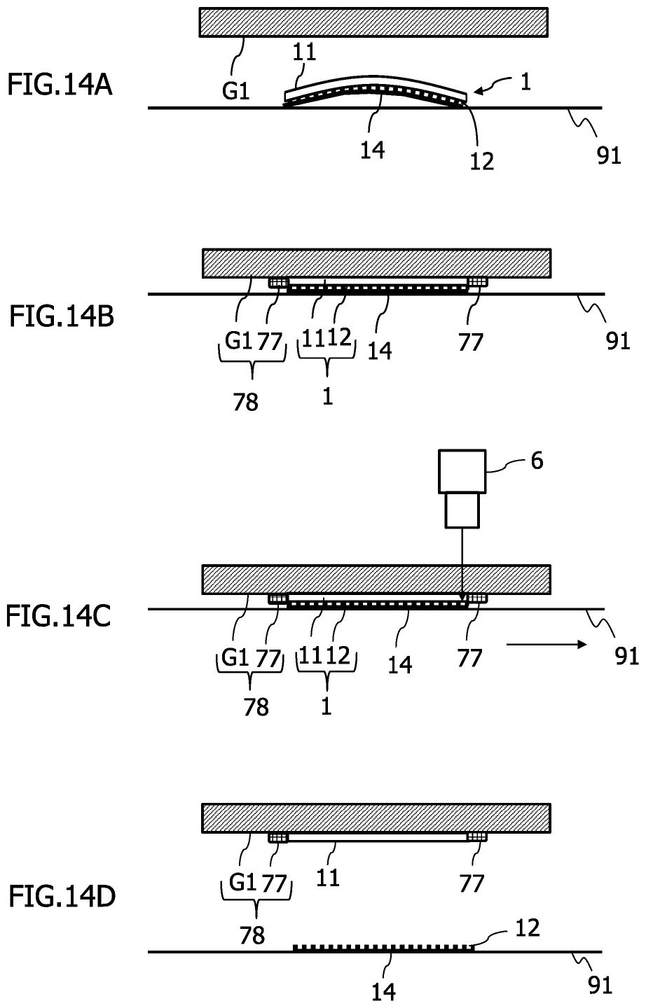

FIGS. 14A to 14D are time-sequence diagrams showing the progress of flattening and laser lift-off processing according to the fifth embodiment. In the fifth embodiment, the ends, distal from the sapphire substrate 11, of the micro LEDs 12, which are formed on the upper surface of the sapphire substrate 11, are adhered to the film 14. In response to an instruction from the control unit 10a, the elevating mechanism 8 lowers the quartz glass substrate G1 so that it comes into contact with the lower surface of the sapphire substrate 11 which has some warpage (see FIG. 14A).

After the quartz glass substrate G1 comes into contact with the lower surface of the sapphire substrate 11, the elevating mechanism 8 presses the quartz glass substrate G1 onto the laminate 1 so as to flatten the sapphire substrate 11 of the laminate 1. In the fifth embodiment, the laser lift-off apparatus 1 further includes a mechanism (not shown) for bonding the peripheral portion of the sapphire substrate 11 onto the quartz glass substrate G1 with a fixing member 77. The fixing member 77 may be an adhesive, for example. Using the above configuration, the quartz glass substrate G1 and the laminate 1 are integrated together (see FIG. 14B). In other words, the quartz glass substrate G1 and the fixing member 77 collectively function as a flattening jig 78 configured to maintain flatness of the sapphire substrate 11.

Then, in the fifth embodiment, after the laminate 1 is fixed by adsorption or suction on the stage 91 and positioned so that the processing start position is placed immediately below the reducing optical system 6, the laser lift-off processing is performed on the laminate 1 (see FIG. 14C). Thereby, the micro LEDs 12 are sequentially separated from the sapphire substrate 11 (see FIG. 14D).

As described above, in the fifth embodiment as well, the laminate 1 is irradiated with the laser light L in a state in which the sapphire substrate 11 is flattened, and thus, the focal point of the laser light L is constantly placed at appropriate positions. Accordingly, the laser lift-off processing can be performed satisfactorily.

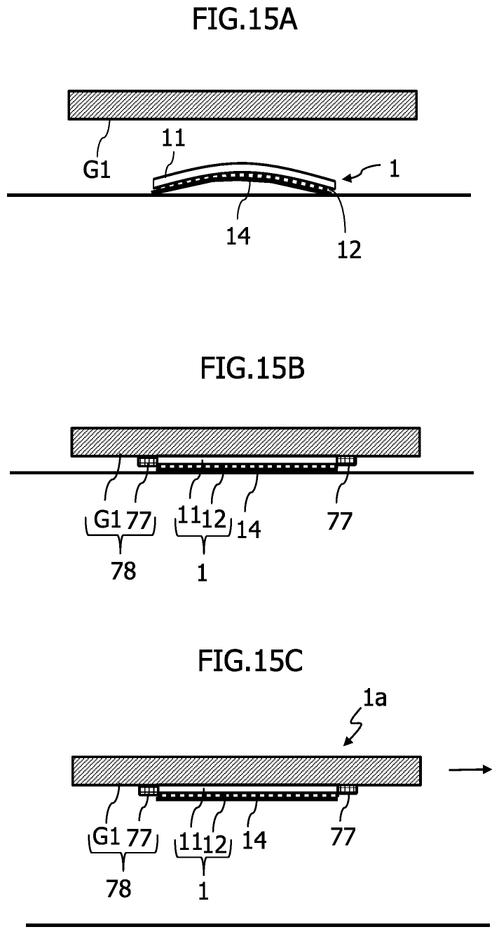

Next, a modification of the fifth embodiment will be described. FIGS. 15A to 15C are diagrams illustrating the modification of the fifth embodiment. In this modification, the flattening processing shown in FIGS. 14A and 14B is performed on the laminate 1 at a location other than on the stage 91 (see FIGS. 15A and 15B). After that, the flattening jig 78 and the laminate 1 to which the film 14 is adhered may be conveyed together, as an assembly 1a, onto the stage 91. In other words, the assembly 1a may be prepared in advance. Even with such a configuration, the laminate 1 is irradiated with the laser light L in a state in which the sapphire substrate 11 is flattened, and thus, the focal point of the laser light L is constantly placed at appropriate positions. Accordingly, in this modification as well, the laser lift-off processing can be performed satisfactorily.

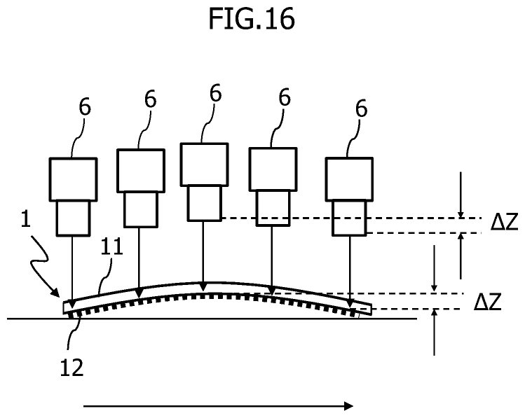

Next, a comparative example will be described. FIG. 16 is a diagram illustrating the comparative example. In the comparative example, laser lift-off processing is performed on the laminate 1 in a state in which the sapphire substrate 11 has a warpage (ΔZ). Here, when the laminate 1 having the sapphire substrate 11 with poor flatness (having a flatness (ΔZ) of 100 μm, for example) is irradiated with the laser light L in the laser lift-off processing, the focal depth of the laser light L or the height of the substrate needs to be adjusted for each irradiation so that the processing is performed at a constant distance. Otherwise, the boundary portions between the sapphire substrate 11 and the micro LEDs 12 may not be reliably processed. FIG. 16 illustrates variation, depending on the warpage of the sapphire substrate 11, of the positional relationship between the reducing optical system 6 and the sapphire substrate 11. For example, when the laser lift-off processing is performed on the laminate 1 having a warpage of ΔZ in the sapphire substrate 11, it is necessary to adjust the focal point of the laser light L in accordance with ΔZ such that the focal point is constantly placed at appropriate laser irradiation positions.

In contrast, in the above embodiments, the laser lift-off processing can be reliably performed on the laminate 1 without adjusting (controlling) the height of the sapphire substrate 11 relative to the laser light L as in the comparative example. Thus, techniques according to the embodiments described above facilitates separation of the micro LEDs 12 from the sapphire substrate 11.

It should be noted that the entire contents of Japanese Patent Application No. 2017-210858, filed on Oct. 31, 2017, based on which convention priority is claimed, is incorporated herein by reference.

It should also be understood that many modifications and variations of the described embodiments of the invention will be apparent to one of ordinary skill in the art without departing from the spirit and scope of the present invention as claimed in the appended claims.

What is claimed is:

1. A laser lift-off processing method performed on a laminate including a disk-shaped sapphire substrate, which is to be removed, and a plurality of micro LEDs formed on a first surface of the sapphire substrate, by irradiating the laminate with pulse-oscillated laser light from a second surface of the sapphire substrate and thereby separating the micro LEDs from the sapphire substrate, the method including:
flattening the sapphire substrate by pressing the sapphire substrate with a force external to the laminate so as to correct a warpage of the sapphire substrate; and
separating the micro LEDs from the sapphire substrate by irradiating the laminate with the laser light from the second surface in a state in which the sapphire substrate is flattened while moving, in a horizontal plane, the laminate placed on a stage of a conveying mechanism relative to an irradiation optical system from which the laser light exits, such that a focal point of the laser light sequentially coincides with boundary portions between the sapphire substrate and the micro LEDs.

2. The laser lift-off processing method according to claim 1, wherein the flattening the sapphire substrate is performed by:
lowering a transmissive member that transmits the laser light to the laminate so that the transmissive member comes into contact with the second surface of the sapphire substrate, and
then lowering a flattening jig configured to press a peripheral portion of the transmissive member so that the flattening jig causes the transmissive member to press the sapphire substrate so as to correct the warpage of the sapphire substrate.

3. The laser lift-off processing method according to claim 1, wherein the flattening the sapphire substrate is performed using a press member formed by integrally combining a transmissive member that transmits the laser light and a flattening jig configured to press a peripheral portion of the transmissive member, by lowering the press member to the laminate so that the transmissive member comes into contact with the second surface of the sapphire substrate, thereby pressing the sapphire substrate so as to correct the warpage of the sapphire substrate.

4. The laser lift-off processing method according to claim 1, wherein the flattening the sapphire substrate is performed by:
lowering a transmissive member that transmits the laser light so that the transmissive member comes into contact with the second surface of the sapphire substrate,
pressing the transmissive member onto the sapphire substrate so as to correct the warpage of the sapphire substrate and flatten the sapphire substrate, and
then fixing a peripheral portion of the sapphire substrate to the transmissive member with an adhesive.

5. A flattening jig used in a laser lift-off processing method performed on a laminate including a disk-shaped sapphire substrate, which is to be removed, and a plurality of micro LEDs formed on a first surface of the sapphire substrate, by irradiating the laminate with pulse-oscillated laser light from a second surface of the sapphire substrate and thereby separating the micro LEDs from the sapphire substrate, the flattening jig being configured to flatten the sapphire substrate by pressing the sapphire substrate so as to correct a warpage of the sapphire substrate, the flattening jig comprising:
a ring member having a diameter greater than a diameter of the sapphire substrate;
an inner annular portion having a flat surface protruding radially inward from an upper end periphery of the ring member; and
an outer annular portion having a flat surface protruding radially outward from a lower end periphery of the ring member.

6. The flattening jig according to claim 5, wherein a ring-shaped cushion member is provided on a lower surface of the inner annular portion.

7. The flattening jig according to claim 5, further comprising a disk-shaped transmissive member that transmits the laser light and is provided to face a lower surface of the inner annular portion,
wherein an upper surface of a peripheral portion of the transmissive member is fixed to the lower surface of the inner annular portion.

8. The flattening jig according to claim 7, wherein a ring-shaped cushion member is provided on a lower surface of the peripheral portion of the transmissive member.
